(19) United States
(12) Patent Application Publication
(10) Pub. No.: US 2012/0250267 A1
(43) Pub. Date: Oct. 4, 2012

(54) RADIO FREQUENCY COMMUNICATION MODULE

(76) Inventors: Dong Hwan Lee, Suwon-si (KR); Hee Soo Yoon, Suwon-si (KR); Su Bong Jang, Anyang-si (KR)

(21) Appl. No.: 13/330,625

(22) Filed: Dec. 19, 2011

(30) Foreign Application Priority Data
Mar. 29, 2011 (KR) 10-2011-0028289

(51) Int. Cl. H05K 7/00

(52) U.S. Cl. 361/748

(57) ABSTRACT

Disclosed herein is a radio frequency (RF) communication module. The RF communication module includes: a main substrate having a plurality of electronic components mounted on an upper surface thereof and having at least one ground pad formed at corners thereof; an insulating material encapsulating the electronic components mounted on the upper surface of the main substrate and having a metal layer formed on an upper surface thereof; and a side shielding layer formed on a side of the insulating material.

### CROSS REFERENCE(S) TO RELATED APPLICATIONS

This application claims the benefit under 35 U.S.C. Section 119 of Korean Patent Application Serial No. 10-2011-0028289, entitled “Radio Frequency Communication Module” filed on Mar. 29, 2011, which is hereby incorporated by reference in its entirety into this application.

### BACKGROUND OF THE INVENTION

1. Technical Field

The present invention relates to a radio frequency (RF) communication module, and more particularly, to an RF communication module capable of shielding an electromagnetic wave radiated to the outside by forming metal layers on each of an upper surface and a side of an insulating material protecting electronic components.

2. Description of the Related Art

Recently, the portability of information technology (IT) devices including a mobile phone has been emphasized, and portable IT devices have gradually become slim in order to improve the portability and facilitate space utilization. Therefore, there is a trend toward the slimness and lightness of various forms of electronic devices mounted in the portable IT device.

The trend toward the slimness and lightness may be applied to a mobile communications terminal such as a mobile phone, a smart phone, etc., a portable device such as a portable multimedia player (PMP), a MPEG layer 3 (MP3) player, etc., a media player such as a television, a monitor, etc., or the like.

Meanwhile, in electronic devices such as a mobile communications terminal or a recent media player, at least one of a high frequency device for communicating with other devices and a communication module implementing components such as an integrated circuit chip, etc., as a single package has been used.

Most of these electronic devices generate electromagnetic wave interference such as electromagnetic interference (EMI) at the time of a unique electric operation thereof. For example, an electric or magnetic energy generated from the electronic device is radiated through a predetermined path to thereby cause electromagnetic interference with other devices or the electronic device is subjected to electromagnetic interference due to an electric or magnetic energy conducted from the outside.

The electromagnetic wave interference between the electronic devices may serve as a serious fault factor capable of hindering a unique electric operation of the electronic device. Therefore, according to the related art, the outside of the electronic device or a module used in the electronic device has been shielded by a metal tool to reduce the radiation of an electromagnetic wave, such that the electromagnetic wave interference between the electronic devices may be somewhat solved.

As the typical process of shielding electromagnetic wave according to the related art, a process of molding an outline of a module using a molding compound or attaching a shield case made of a metal material to the outside of the module has been mainly used. However, in this process, since a substrate and the shield case should be bonded to each other so that they may be electrically connected to each other using a connecting method such as soldering, etc., a manufacturing cost for an assembling process has increased and volume has increased due to a space formed in order to prevent a short-circuit between the shield case made of the metal material and components, such that the demand for the slimness and lightness of the electronic device may not be satisfied.

In order to solve the problem that the demand for the slimness and lightness of the electronic device may not be satisfied, a method of spray-coating, plating or depositing a conductive material such as silver (Ag) or copper (Cu) on a surface of a molding material of the module to thereby form a metal layer and grounding the metal layer to the substrate to thereby form a shielding layer has been used. However, in the method, an expensive mold is required due to characteristics of molding fixing mainly using an EMC and a separate compressing equipment is required, such that a manufacturing cost increases.

In addition, the metal layer is formed to have a thin thickness of about 10 μm at the most, such that a shielding efficiency of the electromagnetic wave may be reduced.

### SUMMARY OF THE INVENTION

An object of the present invention is to provide a radio frequency (RF) communication module capable of allowing an electromagnetic wave generated in a plurality of electronic components to be shielded by stacking and compressing an insulating material on a main substrate having the plurality of electronic components mounted thereon and forming shielding layers on each of upper and lower surfaces of the insulating material.

According to an exemplary embodiment of the present invention, there is provided a radio frequency (RF) communication module including: a main substrate having a plurality of electronic components mounted on an upper surface thereof and having at least one ground pad formed at corners thereof; an insulating material encapsulating the electronic components mounted on the upper surface of the main substrate and having a metal layer formed on an upper surface thereof; and a side shielding layer formed on a side of the insulating material.

The main substrate may be a multi-layer substrate and include a ground (GND) stacked on at least one layer in an inner portion thereof.

The ground may be electrically connected to the ground pad formed at the corners of the main substrate through vias or through-holes.

The insulating material may be formed of a resin coated copper foil (RCC) substrate having the metal layer stacked on the upper surface thereof, the metal layer being made of a conductive material, and be formed as a molding part having an upper shielding layer formed thereon by being stacked and compressed on the upper surface of the main substrate in a state in which it has the metal layer stacked thereon.

The insulating material may be formed as a molding part encapsulating the upper surface of the main substrate and the electronic components by being stacked on the upper surface of the main substrate in a provisionally hardened state when it is stacked thereon and being hardened by compression.

The metal layer may be formed on the upper surface of the insulating material after a RCC substrate stacked as a multi-layer is stacked on the upper surface of the main substrate and is hardened by compression and serve as an upper shielding layer.

The metal layer may be formed of a metal plate made of silver (Ag) or copper (Cu), and be formed of a copper foil when a RCC substrate having the metal layer stacked on the upper surface thereof is stacked on the main substrate.

The metal layer may be formed to have a thickness of 30 to 40 μm.

The side shielding layer may be formed on a side of the insulating material by spray coating using a conductive material including silver (Ag) or copper (Cu).

### BRIEF DESCRIPTION OF THE DRAWINGS

FIG. 1 is an exploded perspective view of a radio frequency (RF) communication module according to an exemplary embodiment of the present invention;

FIG. 2 is a perspective view of an RF communication module according to an exemplary embodiment of the present invention; and

FIG. 3 is a side view of an RF communication module according to an exemplary embodiment of the present invention.

### DESCRIPTION OF THE PREFERRED EMBODIMENTS

The acting effects and technical configuration with respect to the objects of a radio frequency (RF) communication module according to the present invention will be clearly understood by the following description in which exemplary embodiments of the present invention are described with reference to the accompanying drawings.

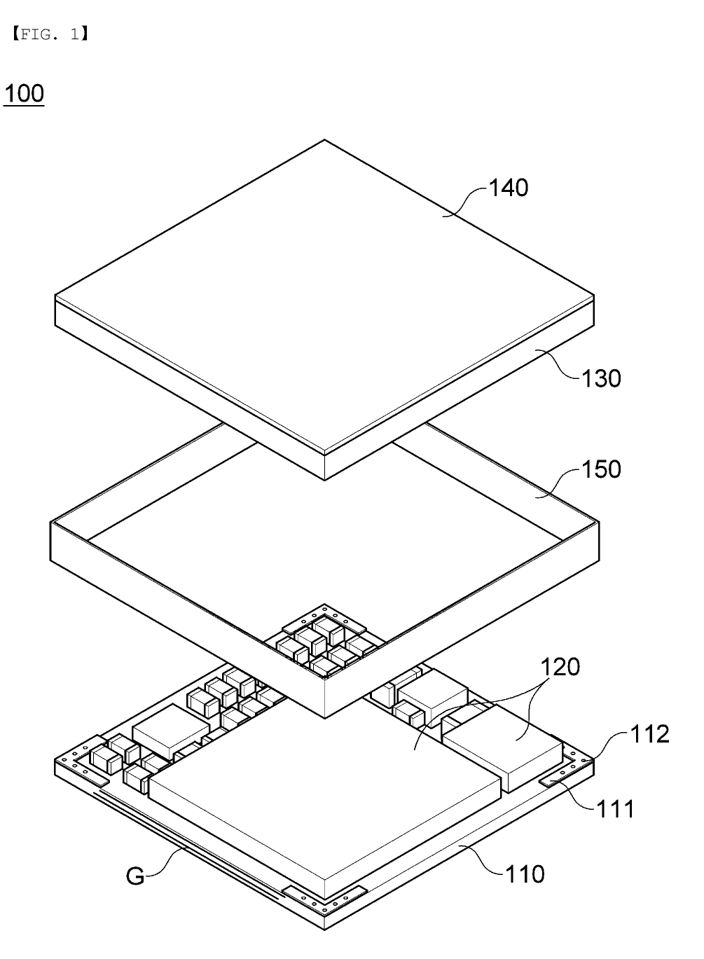

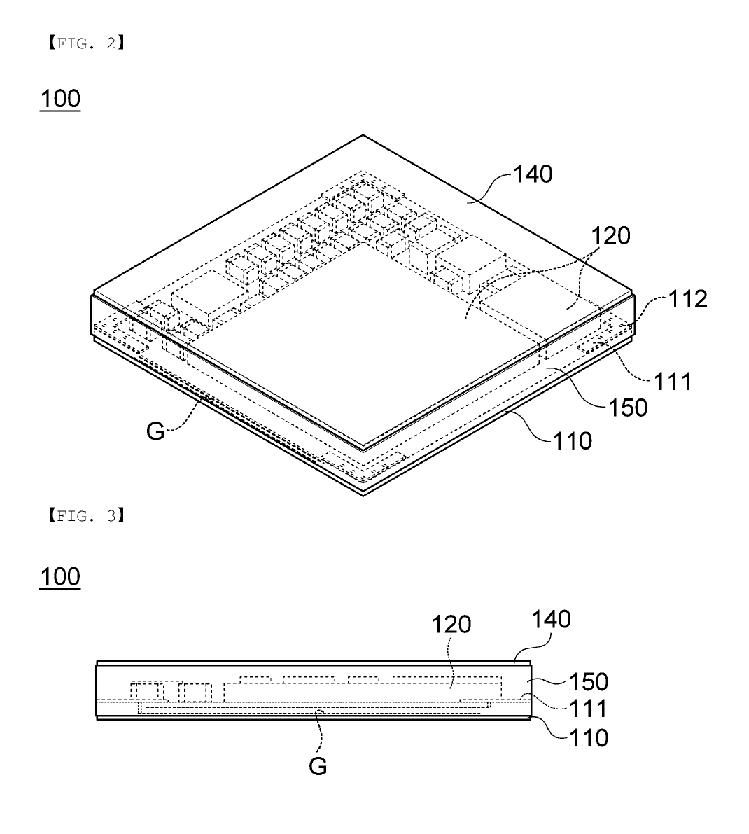

FIG. 1 is an exploded perspective view of a radio frequency (RF) communication module according to an exemplary embodiment of the present invention; FIG. 2 is a perspective view of an RF communication module according to an exemplary embodiment of the present invention; and FIG. 3 is a side view of an RF communication module according to an exemplary embodiment of the present invention.

As shown in FIGS. 1 to 3, an RF communication module 100 according to an exemplary embodiment of the present invention may be mainly configured to include a main substrate 110 having a plurality of electronic components 120 mounted thereon, an insulating material 130 covering an upper surface of the main substrate 110 so that the electronic components 120 are embedded therebetween, and a metal layer 140 and a side shielding layer 150 each formed on an upper surface and a side of the insulating material 130.

The main substrate 110 may include the plurality of electronic components 120 mounted over most of an upper surface area thereof and at least one ground pad 111 formed at each of the corners thereof. In addition, the main substrate 110, which is a multi-layer substrate, may be a ceramic substrate or a multi-layer printed circuit board (PCB).

Here, the main substrate 110 having a multi-layer structure may include grounds G stacked on at least one layer in an inner portion thereof, wherein the respective grounds G may be electrically connected to the ground pad 111 formed at the corner of the main substrate 110 through vias 112, through-holes, or the like.

The electronic components 120 may be chip components such as a multi-layer ceramic capacitor (MLCC), a chip inductor, and a chip resistor that are electrically connected to the main substrate 110 to thereby perform electric operations, and may include circuit devices, etc., such as an integrated circuit, a capacitor, or a resistor. In addition, the electronic component 120 itself may be a high frequency module performing an independent electric function.

Further, the insulating material 130 encapsulating the upper surface of the main substrate 110 may serve to protect the electronic components 120 mounted on the upper surface of the main substrate from external shock and may prevent a short-circuit between the electronic components 120 while individually enclosing each of the electronic components 120.

The insulating material 130 may be formed of a resin coated copper foil (RCC) substrate.

The RCC substrate, which is a buildup substrate insulator mainly used during a process of manufacturing a substrate, may be an insulating stack formed by stacking a plurality of thin plate members and cover the main substrate 110 in a state in which it has the metal layer 140 stacked on an upper layer thereof.

In this configuration, the metal layer 140 serves as an upper shielding layer of the RCC substrate, which is the insulating material 130, and the insulating material 130 serves as a molding part in a state in which it encapsulates the main substrate 110.

In addition, when the insulating material 130 is stacked on an upper surface of the main substrate 110, it is stacked while maintaining a state in which a plurality of plate members are provisionally hardened at a predetermined height, and is hardened by applying heat thereto simultaneously with compressing an upper surface thereof. As a result, the insulating material may be formed as a molding part.

Here, the insulating material 130 may be formed to have a thickness higher than those of the electronic components 120 so that it may encapsulate up to an upper surface of the electronic components 120 mounted on the main substrate 110. In addition, a stacking height of the insulating material 130 should be controlled on the main substrate 110 in consideration of a height at which it may cover up to the upper surface of the electronic components 120 after being hardened due to characteristics of the RCC substrate having a significantly reduced thickness after being hardened.

Here, the insulating material 130 formed of the RCC substrate has the metal layer 140 stacked on the upper layer thereof, such that when it is hardened on the main substrate 110 and encapsulates the main substrate 110, an electromagnetic wave mainly radiated upwardly from the electronic components 120 may be shielded through the metal layer 140 serving as an upper shielding layer.

In addition, the metal layer 140 stacked on the upper layer of the RCC substrate, which is an insulating stack, may have a relatively thick thickness of 30 to 40 μm, such that it may improve a shielding efficiency as compared to a case in which the upper shielding layer is formed by the spray coating method using a conductive material according to the related art.

The metal layer 140 may be formed of a metal plate made of silver (Ag) or copper (Cu). When the insulating material 130 covers the main substrate 110 as the RCC substrate in a state in which the metal layer 140 is stacked on the upper surface thereof, the metal layer 140 may be formed of a copper foil made of a copper (Cu) material.

Meanwhile, the insulating material 130 may be formed on the main substrate 110 as the molding part enclosing the electronic components 120 mounted on the main substrate 110 by stacking the plurality of thin plate members thereon in a state in which the metal layer 140 is excluded and applying heat and pressure only to the plurality of thin plate members, that is, performing heat compression on the plurality of thin plate members.

The insulating material 130 may be formed by stacking the RCC substrate of the insulator in which the metal layer is excluded and then hardening it by heat compression and have the metal layer 140 formed on the upper surface thereof, wherein the metal layer 140 is made of silver (Ag) or copper (Cu) and serves as the upper shielding layer.

Here, the metal layer 140 formed on the upper surface of the insulating material 130 may be formed to have a relatively thick thickness of 30 to 40 μm.

In addition, the insulating material 130 having the metal layer 140 formed on the upper surface thereof may have the side shielding layer 150 formed on the side of the insulating material 130. The side shielding layer 150 may contact the metal layer 140 at an upper portion thereof to be electrically connected thereto and may be electrically connected to the ground pad 111 formed at the corner of the main substrate 110 at a lower portion thereof.

Therefore, the metal layer 140 and the side shielding layer 150 that are made of a metal material and enclose the upper surface and the side of the insulating material 130 are electrically connected to the ground pad 111 of the main substrate 110 and the ground pad 111 is connected to the ground G stacked in the inner portion of the main substrate 110 through the vias 112, thereby making it possible to use the metal layer 140 and the side shielding layer 150 that enclose the insulating material 130 as extended grounds and block radiation noise generated from the electronic components 120 from flowing out to the outside through the metal layer 140 and the side shielding layer 150.

Here, the side shielding layer 150 may be electrically connected to the ground G of an inner layer of the main substrate 110 while being electrically connected to the ground pad 111 of the main substrate 110.

In addition, the side shielding layer 150 may be formed to have a thin film shape by performing spray coating or deposition using a conductive material such as silver (Ag) or copper (Cu). When the metal layer 140 formed on the upper portion of the insulating material 130 is formed of the copper foil made of the copper material, the side shielding layer 150 may be made of the same kind of copper (Cu) material as that of the metal layer 140 so that electric connection therebetween may be easily performed.

As described above, the RF communication module according to the exemplary embodiment of the present invention may be manufactured by mounting the electronic components on a unit main substrate individually cut in a form as shown in FIGS. 1 to 3 and forming the insulating material encapsulating the unit main substrate and including the metal layer.

Meanwhile, when the RF communication module is manufactured, a circular plate in which a plurality of main substrates are interconnected and a scribe cutting line is formed, the electronic components are mounted on each of the plurality of main substrates, the RCC substrate, which is the insulating material, having the same size as that of the circular plate, that is, a size capable of covering the entire upper surface of the circular plate is formed and hardened, and unit module molded as the insulating material along the scribe cutting line is then formed.

Then, the side shielding layer is formed on the side of the insulating material of the unit module by performing spray coating, or the like, to manufacture the RF communication module, thereby making it possible to mass-produce the RF communication module and significantly reduce a cost due to the reduction in the number of processes of manufacturing the RF communication module.

As described above, in the RF communication module according to the exemplary embodiment of the present invention, the RCC substrate used as a build-up insulator of the substrate is formed as the molding part protecting the plurality of electronic components, such that there is no need to separately include a high cost mold for molding, thereby making it possible to reduce a manufacturing cost.

In addition, in the RF communication module according to the exemplary embodiment of the present invention, the RCC substrate is formed as the molding part, the upper shielding layer is formed of the copper foil at a top layer of the RF communication module, and the insulating material formed below the copper foil has a low dielectric constant, thereby making it possible to improve a shielding efficiency of radiation noise.

Further, in the RF communication module according to the exemplary embodiment of the present invention, the metal layer formed on the upper surface of the RCC substrate formed as the molding part has a thick thickness, making it possible to efficiently block the noise mainly radiated upwardly of the RF communication module.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A radio frequency (RF) communication module comprising:
a main substrate having a plurality of electronic components mounted on an upper surface thereof and having at least one ground pad formed at corners thereof;
an insulating material encapsulating the electronic components mounted on the upper surface of the main substrate and having a metal layer formed on an upper surface thereof; and
a side shielding layer formed on a side of the insulating material.

2. The RF communication module according to claim 1, wherein the main substrate is a multi-layer substrate and includes a ground (GND) stacked on at least one layer in an inner portion thereof.

3. The RF communication module according to claim 2, wherein the ground is electrically connected to the ground pad formed at the corners of the main substrate through vias or through-holes.

4. The RF communication module according to claim 1, wherein the insulating material is formed of a resin coated copper foil (RCC) substrate having the metal layer stacked on the upper surface thereof, the metal layer being made of a conductive material.

5. The RF communication module according to claim 1, wherein the insulating material is formed as a molding part encapsulating the electronic components by stacking a plurality of plate members on the main substrate in a provisionally hardened state and hardening the plurality of thin plate members by heat compression.

6. The RF communication module according to claim 1, wherein the metal layer is formed of a metal plate made of silver (Ag) or copper (Cu).

7. The RF communication module according to claim 6, wherein the metal layer is formed to have a thickness of 30 to 40 μm.

8. The RF communication module according to claim 1, wherein the side shielding layer is formed as a coating layer using a conductive material including silver (Ag) or copper (Cu).

9. The RF communication module according to claim 1 or 2, wherein the side shielding layer has an upper portion contacting the metal layer to be electrically connected thereto and has a lower portion electrically connected to the ground pad formed at the corner of the main substrate, thereby forming a ground area extended from the ground stacked in an inner portion of the main substrate.
